(19) United States
(12) Patent Application Publication
(10) Pub. No.: US 2005/0170079 A1
(43) Pub. Date: Aug. 4, 2005

(54) Method for manufacturing wiring substrate and method for manufacturing electronic device

(76) Inventors: Hidemichi Furihata, Suwa (JP); Satoshi Kimura, Suwa (JP); Minoru Marumo, Suwa (JP)

Correspondence Address: HARNESS, DICKEY & PIERCE, P.L.C., P.O. BOX 828, BLOOMFIELD HILLS, MI, 48303, US

(21) Appl. No.: 11/050,253

(22) Filed: Feb. 3, 2005

(30) Foreign Application Priority Data
Feb. 4, 2004 (JP) 2004-028119

(51) Int. Cl. H05K 3/00; C23C 28/00; B28B 19/00; H01L 21/44; B05D 5/12

(52) U.S. Cl. 427/99.1; 427/96.1; 427/99.5

(57) ABSTRACT

A method for manufacturing a wiring substrate includes the steps of (a) providing a catalyst in first and second areas of a substrate, (b) irradiating a vacuum ultraviolet radiation to the second area of the substrate to thereby break down an interatomic bond in the second area of the substrate, (c) washing the substrate to thereby remove a portion of the catalyst provided in the second area, and (d) depositing a metal layer on a portion of the catalyst remaining in the first area to thereby form a wiring composed of the metal layer along the first area.

### RELATED APPLICATIONS

This application claims priority to Japanese Patent Application No. 2004-028119 filed Feb. 4, 2004 which is hereby expressly incorporated by reference herein in its entirety.

### BACKGROUND

1. Technical Field

The present invention relates to a method for manufacturing wiring substrates and a method for manufacturing electronic devices.

2. Related Art

A subtractive method and an additive method are known as a method for forming wirings on a flexible substrate. In the subtractive method, a metal layer is formed over the entire surface of a flexible substrate, a photoresist is formed on the metal layer by patterning, and the metal layer is etched by using the photoresist as a barrier. In the additive method, a photoresist is formed on a flexible substrate by patterning, and a metal layer is deposited by a plating process in an opening section in the photoresist.

These methods entail problems concerning consumptions of resources and raw material, in view of the fact that the photoresist is finally removed, and further in view of the fact that a part of the metal layer is removed in the subtractive method. Also, they require the steps of forming and removing a photoresist, which results in a problem of a large number of manufacturing steps. Furthermore, because the measurement accuracy of wirings depends on the resolution of a photoresist, there is a limit in forming wirings at a higher level of accuracy.

It is an object of the present invention to deposit a metal layer only in a required portion, and form wirings with a simple manufacturing process.

### SUMMARY

A method for manufacturing a wiring substrate in accordance with the present invention includes the steps of:
(a) providing a catalyst in first and second areas of a substrate;
(b) irradiating a vacuum ultraviolet radiation to the second area of the substrate to thereby break down an interatomic bond in the second area of the substrate;
(c) washing the substrate to thereby remove a portion of the catalyst provided in the second area; and
(d) depositing a metal layer on a portion of the catalyst remaining in the first area to thereby form a wiring composed of the metal layer along the first area.

According to the present invention, the catalyst is patterned by irradiation of a vacuum ultraviolet radiation. By this, a metal layer can be precipitated only to a required portion along a predetermined pattern configuration. Accordingly, for example, there is no need to form a mask with a resist layer, and a waste of material can be reduced, and highly accurate wirings can be formed at a low cost with a simple and short-time manufacturing process.

In the method for manufacturing a wiring substrate, before the step (a), a reforming layer including a C—F bond may be formed in the substrate. By this, effects similar to substrate cleaning and surface roughening treatment can be obtained. Also, due to the fact that the reforming layer has a water-repelling function, the moisture resistance of the substrate improves.

In the method for manufacturing a wiring substrate, there may be further provided, before the step (b), the step of providing a surface-active agent in the first and second areas of the substrate, wherein, in the step (b), the catalyst may be provided on the surface-active agent. By this, the catalyst can be stably provided.

In the method for manufacturing a wiring substrate, the surface-active agent may be a cationic system surface-active agent.

In the method for manufacturing a wiring substrate, the surface-active agent may be an anionic system surface-active agent.

In the method for manufacturing a wiring substrate, the substrate may have at least one of a C—C, C═C, C—F, C—H, C—Cl, C—N, C—O, N—H and O—H bond.

In the method for manufacturing a wiring substrate, the substrate may have at least a C═C bond, and the vacuum ultraviolet radiation may have at least a property that can break down the C═C bond.

In the method for manufacturing a wiring substrate, a light source of the vacuum ultraviolet radiation may be an excimer lamp having Xe gas enclosed therein.

In the method for manufacturing a wiring substrate, in the step (a), the substrate may be dipped in a solution including tin chloride, and then dipped in a catalyst liquid including palladium chloride, to thereby deposit palladium as the catalyst.

In the method for manufacturing a wiring substrate, in the step (a), the substrate may be dipped in a catalyst liquid including tin-palladium to remove tin from the substrate, to thereby deposit palladium as the catalyst.

A method for manufacturing an electronic device in accordance with the present invention includes the method for manufacturing a wiring substrate described above, and further includes the steps of mounting a semiconductor chip having an integrated circuit on the wiring substrate, and electrically connecting the wiring substrate to a circuit substrate. According to the present invention, a waste of material can be reduced, and highly accurate wirings can be formed at a low cost with a simple and short-time manufacturing process.

### BRIEF DESCRIPTION OF THE DRAWINGS

FIG. 1(A)-FIG. 1(C) are views illustrating a method for manufacturing a wiring substrate in accordance with an embodiment of the present invention.

FIG. 2(A)-FIG. 2(C) are views illustrating the method for manufacturing a wiring substrate in accordance with the embodiment of the present invention.

FIG. 3(A)-FIG. 3(D) are views illustrating a method for manufacturing a wiring substrate in accordance with an embodiment of the present invention.

FIG. 4(A)-FIG. 4(C) are views illustrating the method for manufacturing a wiring substrate in accordance with the embodiment of the present invention.

FIG. 5 is a view illustrating an electronic device in accordance with an embodiment of the present invention.

### DETAILED DESCRIPTION

Embodiments of the present invention are described below with reference to the accompanying drawings.

### First Embodiment

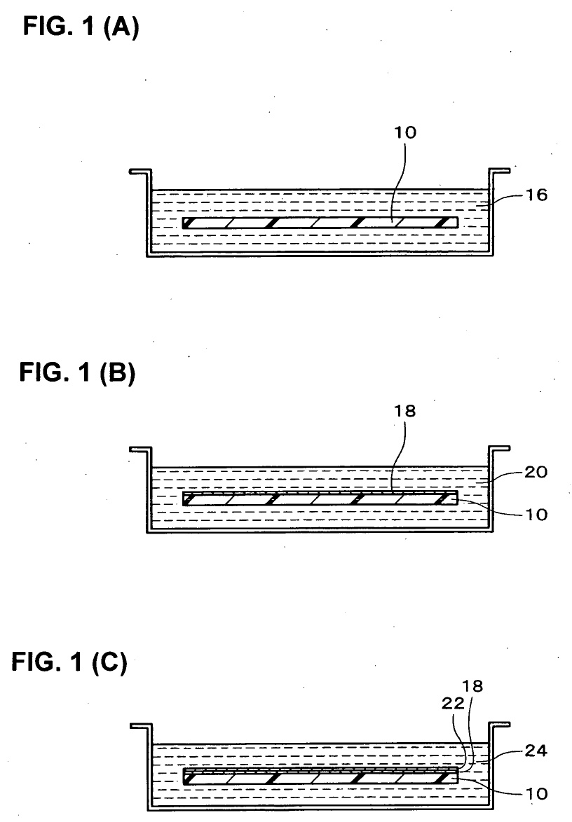

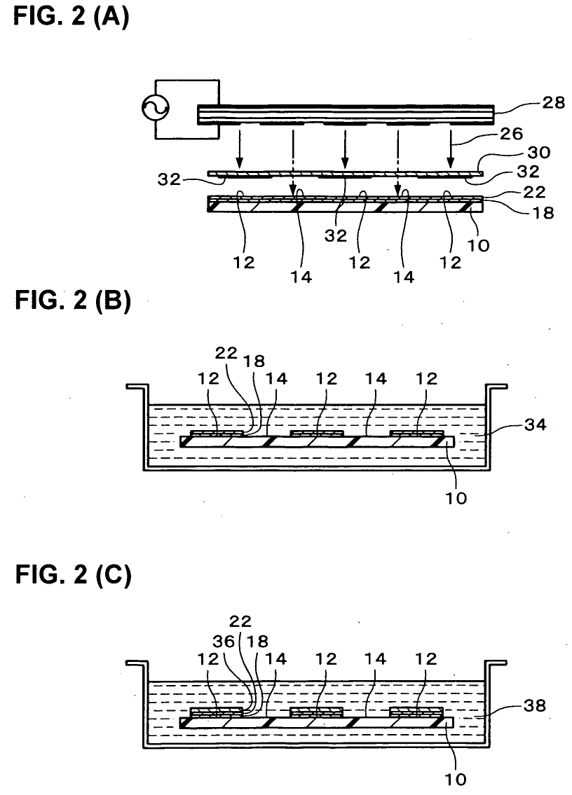

FIG. 1(A)-FIG. 2(C) are views illustrating a method for manufacturing a wiring substrate in accordance with an embodiment of the present invention. In the present embodiment, a wiring substrate is manufactured using an electroless plating method.

A substrate (sheet) 10 may be a flexible substrate. As the flexible substrate, a FPC (Flexible Printed Circuit), a COF (Chip On Film) substrate, or a TAB (Tape Automated Bonding) substrate may be used. The substrate 10 is formed from an organic material (for example, resin). As the substrate 10, a polyimide substrate or a polyester substrate may be used. The substrate 10 has an organic interatomic bond. The substrate 10 may have at least one of a C—C, C═C, C—F, C—H, C—Cl, C—N, C—O, N—H and O—H bond. The substrate 10 may have at least a C═C bond. In the present embodiment, a wiring is formed on one of surfaces of the substrate 10. Alternatively, wirings may be formed on both of the surfaces of the substrate 10. The substrate 10 has a first area 12 and a second area 14 (see FIG. 2 (A)). The first area 12 and the second area 14 are areas in the surface of the substrate 10 where wirings are formed.

As shown in FIG. 1(A), first, dirt on the surface of the substrate 10 may be washed (cleaned). As a washing method, the substrate 10 may be dipped in a washing solution 16 such as an acid, an alkali, an organic solvent or water. Concretely, a solution of hydrochloride system or an alcohol such as IPA or the like may be used as the washing solution 16. In the case of organic material, the surface potential (surface potential in a liquid) of the substrate 10 is often a negative potential.

The substrate 10 may be washed with an alkali by dipping in an alkaline solution (for example, an inorganic alkaline solution). More specifically, the substrate 10 may be dipped in or washed with a solution of sodium hydroxide in a concentration of 1 wt %-10 wt % at room temperature for about 10-60 minutes (for example, 30 minutes). In this case, nonuniformity of the surface potential in the first and second areas 12 and 14 of the substrate 10 can be made uniform to a negative potential. Cleaning and surface roughening treatment of the substrate 10 can be conducted at the same time by the alkali washing. By conducting cleaning and surface roughening treatment, the adhesion of a metal layer (wiring) can be improved.

A surface-active agent 18 may be provided in the first and second areas 12 and 14 of the substrate 10, if necessary, as shown in FIG. 1 (B). In this case, the substrate 10 may be dipped in a surface-active agent solution 20. The surface-active agent 18 may be provided over the entire area of one of the surfaces of the substrate 10.

A cationic system surface-active agent (a cation surface-active agent or one having a property equal to the same) that has a property to make positive ion may be used as the surface-active agent 18. For example, the substrate 10 is dipped in a cation surface-active agent solution of an alkyl ammonium chloride system at room temperature for about 30 seconds to three minutes, and then washed with pure water. Then, the substrate 10 is sufficiently dried in a room temperature atmosphere. When the surface potential of the substrate 10 is a negative potential, the negative potential on the surface of the substrate 10 can be neutralized or reversed to a positive potential by the cationic system surface-active agent used.

As a modified example, an anionic system surface-active agent (an anion surface-active agent or one having a property equal to the same) that has a property to make negative ion may be used as the surface-active agent 18. For example, the substrate 10 is dipped in an anion surface-active agent solution at room temperature for about 30 seconds to three minutes, and then washed with pure water. Then, the substrate 10 is sufficiently dried in a room temperature atmosphere. When the surface potential of the substrate 10 is a negative potential, the use of the anionic system surface-active agent can improve potential nonuniformity caused by dirt or the like on the surface of the substrate 10, and form a stable negative potential surface.

A catalyst (plating catalyst) 22 is provided in the first and second areas 12 and 14 of the substrate 10, as shown in FIG. 1(C). In this case, the substrate 10 may be dipped in a catalyst liquid 24. When the surface-active agent 18 is provided in the first and second areas 12 and 14, the catalyst 22 is provided on the surface-active agent 18. Alternatively, the catalyst 22 may be provided on the surface of the substrate 10 without the surface-active agent 18. The catalyst 22 causes the precipitation of a metal layer (plating layer) in an electroless plating liquid, and may be, for example, palladium. A resin for bonding may not be included in the catalyst 22.

For example, when the catalyst adhesion side is at a positive potential, the substrate 10 is dipped in a catalyst liquid including tin-palladium. More specifically, the substrate 10 is dipped in a tin-palladium colloid catalyst liquid of approximately PH1 for 30 seconds—three minutes at room temperature, and then sufficiently washed with clear water. Tin-palladium colloidal particle has a negative charge, and adheres to the surface of (or the cationic system surface-active agent on) the substrate 10. Then, the substrate 10 is dipped in a solution including a fluoroborate acid at room temperature for 30 seconds—three minutes for activation of the catalyst, and then washed with clear water. As a result, the tin colloidal particle is removed, and palladium alone can be precipitated.

Alternatively, when the catalyst adhesion side is at a negative potential, for example, the substrate 10 may be dipped in a solution including tin chloride having a positive charge, and then dipped in a catalyst liquid including palladium chloride, such that palladium can be precipitated on the surface of (or the anionic system surface-active agent on) the substrate 10. It is noted that the substrate 10 may be dipped in the catalyst liquid for one minute—five minutes, and then washed with pure water.

Besides the abovementioned method, the catalyst 22 may be provided in the first and second areas 12 and 14 of the substrate 10 by a dry film forming method (for example, by a sputter method or a vapor deposition method).

Next, portions of the catalyst 22 (and the surface-active agent 18) provided in the second area 14 among the first and second areas 12 and 14 are removed. In other words, the catalyst 22 is patterned in a manner to remain at least along the first region 12.

As shown in FIG. 2, a vacuum ultraviolet radiation (VUV; vacuum ultraviolet radiation) 26 is irradiated to the second area 14 of the substrate 10. More specifically, a mask 30 is disposed between a source of light 28 and the substrate 10, and the vacuum ultraviolet radiation 26 is irradiated to the substrate 10 through the mask 30. The vacuum ultraviolet radiation 26 is covered by a pattern 32 of the mask 30 and penetrates other areas. When the vacuum ultraviolet radiation 26 is irradiated, the interatomic bond in the second area 14 of the substrate 10 is (chemically) broken down. In the present embodiment, the second area 14 of the substrate 10 is not mechanically cut. According to this method, the vacuum ultraviolet radiation 18 is used mainly for the action of breaking the interatomic bond of the substrate 10, such that its energy consumption can be lowered compared with the case of cutting the substrate 10. As a result, for example, a heat distortion can be prevented from being generated in the substrate 10. Moreover, the method can prevent a part of the substrate 10 from dispersing and adhering to other parts.

It is noted here that, in the present embodiment, the first area 12 is an area where a metal layer (wiring) is formed, and has a predetermined pattern configuration. The second area 14 has a reversed configuration of the first area 12 in the surface of the substrate 10.

The vacuum ultraviolet radiation 26 may have a wavelength of 100 nm-200 nm (for example, 100 nm-180 nm). The vacuum ultraviolet radiation 26 has a property (for example, a wavelength) that can break down the organic interatomic bond. The vacuum ultraviolet radiation 26 may have a property (for example, a wavelength) that can break down at least a C═C bond of the substrate 10. It may have a property (for example, a wavelength) that can break down all of the interatomic bonds (composed of at least one of a C—C, C═C, C—F, C—H, C—Cl or C—N C—O, N—H and O—H bond) of the substrate 10. An excimer lamp enclosing Xe gas therein may be used as the source of light 28 (with a wavelength of 172 nm). Because a condenser lens for laser generation and the scanning time with a laser become unnecessary if the lamp is used, simplification of the manufacturing process can be achieved.

More specifically, a mask 30 is arranged over a wiring forming surface of the substrate 10, as shown in FIG. 2(A). The mask 30 may be a photomask, or may be a metal mask. For example, a high-purity silica glass for vacuum ultraviolet radiation (with a transmittance of vacuum ultraviolet radiation of 80% or more) having a pattern formed with chrome is used as the mask 30. Although the mask 30 is shown to be spaced from and above the substrate 10 in FIG. 2(A), the mask 30 is actually disposed on and in contact with the substrate 10. The source of light 28, the mask 30, and the substrate 10 are disposed in a nitrogen atmosphere. The vacuum ultraviolet radiation 26 is irradiated up to the distance of about 10 mm without attenuating in the nitrogen atmosphere.

When neither the substrate 10 nor the mask 30 comes in contact uniformly due to an elasticity and/or a warp of the substrate 10, an outer circumference portion of the mask 30 may be retained with a holder, and the back of the substrate 10 may be pressed toward the mask 30 side in an area of the same size as the mask 30. The source of light 28 is placed close to the substrate 10 as much as possible (for example, 10 mm or less). For example, as the source of light 28, an excimer VUV/03 Cleaning Unit (Manufacturer name; Ushio Electric Co., Model; UER20-172A/B, and Lamp specification; Dielectric barrier discharge excimer lamp enclosing Xe gas therein) may be used. When the raw material of the substrate 10 consists of polyimide, the output is adjusted to about 10 mW and irradiation is conducted for about ten minutes. The vacuum ultraviolet radiation 26 is irradiated to one of the surfaces of the substrate 10 in the present embodiment. However, when wirings are to be formed on both sides of the substrate 10, the vacuum ultraviolet radiation 26 may be irradiated to each of the faces of the substrate 10 one by one or to both of them at the same time.

Next, as shown in FIG. 2(B), the substrate 10 is washed (for example, by wet washing). By so doing, portions in the substrate 10 where the interatomic bond is broken down are removed. In other words, by washing, portions of the catalyst 22 provided in the second area 14 are removed.

When the surface-active agent 18 is provided, both of the surface-active agent 18 and the catalyst 22 are removed. As the washing method, the substrate 10 may be dipped in a washing solution 34, or a shower thereof may be jetted to the substrate 10. An alkaline solution (a strong alkaline solution or a weak alkaline solution) or pure water may be used as the washing solution 34. Shower washing with pure water or high-pressure jet washing with pure water may be applied as the shower method. Supersonic vibration may be added at the time of washing. In the example shown in FIG. 2(B), by washing, the catalyst 22 (and the surface-active agent 18) remains in the first area 12, and the surface of the substrate 10 (for example, a newly generated surface in which an upper part thereof is removed) is exposed in the second area 14.

A metal layer 36 is deposited to the portion of the catalyst 22 left in the first area 12, as shown in FIG. 2(C). Because the catalyst 22 has been removed in the second area 14, the metal layer 36 is not precipitated on the second area 14. In this manner, the metal layer 36 can be formed in a pattern configuration along the first area 12. The metal layer 36 may be formed with one layer, or may be formed with multiple layers. The material of the metal layer 36 is not limited, and may be, for example, any one of Ni, Au, Ni+Au, Cu, Ni+Cu and Ni+Au+Cu. A catalyst may be selected according to the material of the metal layer 36 to be deposited.

In the example shown in FIG. 2(C), the substrate 10 is dipped in a plating solution 38 mainly containing nickel sulfate hexahydrate (at a temperature of 80° C.) for about one minute—three minutes, to form a nickel layer having a thickness of about 0.1-0.2 μm. Alternatively, the substrate 10 may be dipped in a plating solution mainly containing nickel chloride hexahydrate (at a temperature of 60° C.) for about three minutes—ten minutes, to form a nickel layer having a thickness of about 0.1-0.2 μm. According to the present embodiment, because the catalyst 22 is provided along the first area 12, the metal layer 36 can be selectively formed along the first area 12 of the substrate 10 even without forming a mask with a resist layer or the like.

In this manner, a wiring composed of the metal layer 36 can be formed along the first area 12. A wiring substrate in accordance with the present embodiment includes the substrate 10 and the metal layer (wiring) 36. A plurality of wirings may be formed on the substrate 10, to thereby form one wiring pattern.

In accordance with the present embodiment, the catalyst 22 is patterned by irradiating the vacuum ultraviolet radiation 26. As a result, the metal layer 36 can be precipitated only to a required portion along a predetermined pattern configuration. Therefore, for example, there is no need to form a mask with a resist layer or the like, and a waste of material can be reduced, and wirings can be formed at a low cost with high accuracy, with a simple and short-time manufacturing process.

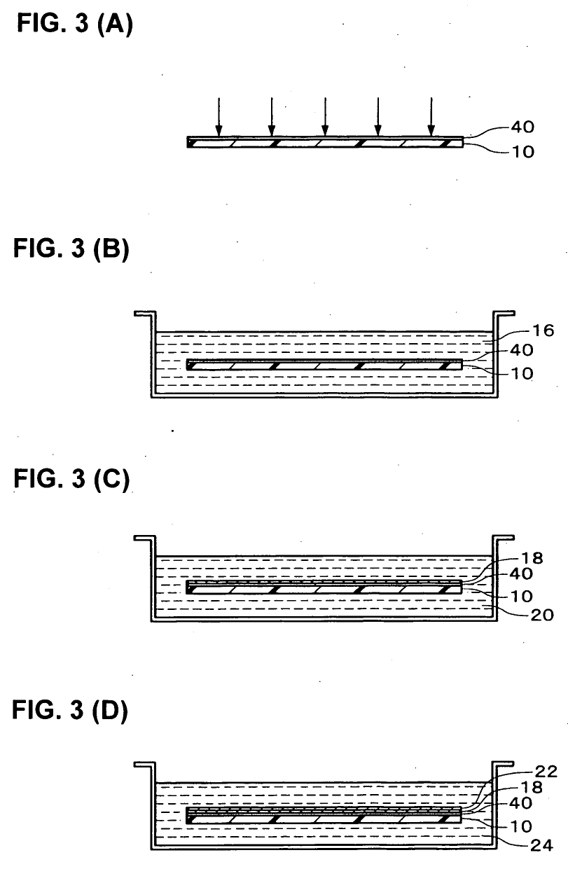

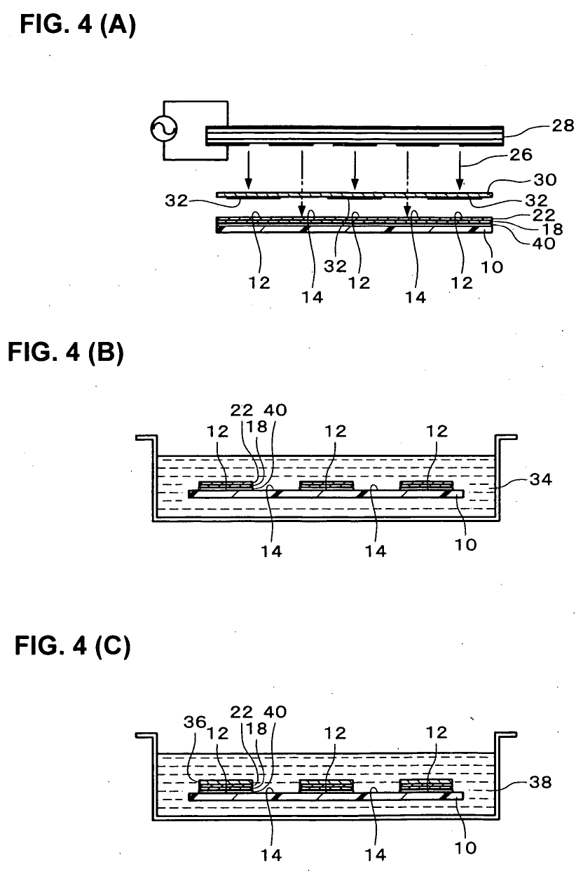

FIG. 3(A)-FIG. 4(C) are views illustrating a method of manufacturing a wiring substrate in accordance with a modified example of the embodiment of the present invention. In this modified example, a reforming layer (fluorinated layer) 40 including a C—F bond is formed to a substrate 10, as shown in FIG. 3(A). In other words, a fluorination treatment is applied to the substrate 10. The reforming layer 40 is formed in a portion of the substrate 10 on the side of first and second areas 12 and 14. The reforming layer 40 may be formed on the entire area of one of the surfaces of the substrate 10. For example, a plasma surface treatment may be applied to the substrate 10 by using a CF₄ gas. Though the thickness of the reforming layer 40 is not limited, it may be, for example, about 10 nm or less. Effects similar to the cleaning and surface roughening treatment of the substrate 10 described above can be achieved by forming the reforming layer 40. Moreover, the moisture resistance of the substrate 10 improves because the reforming layer 40 has a water-repelling function.

Then, dirt on the surface of the substrate 10 may be further washed if necessary (see FIG. 3(B)), a surface-active agent 18 is provided on a reforming layer 40 (see FIG. 3(C)), and a catalyst 22 is provided on the surface-active agent 18 (see FIG. 3(D)). Then, a vacuum ultraviolet radiation 26 is irradiated (see FIG. 4(A)), and the substrate 10 is washed (see FIG. 4(B)), whereby portions of the substrate 10 where the interatomic bond is broken down are removed. In this manner, a wiring can be formed along a predetermined pattern configuration (the first area 12) by depositing a metal layer 36 to portions where the catalyst 22 remains, as shown in FIG. 4(C). The contents described above can be applied to details of the above.

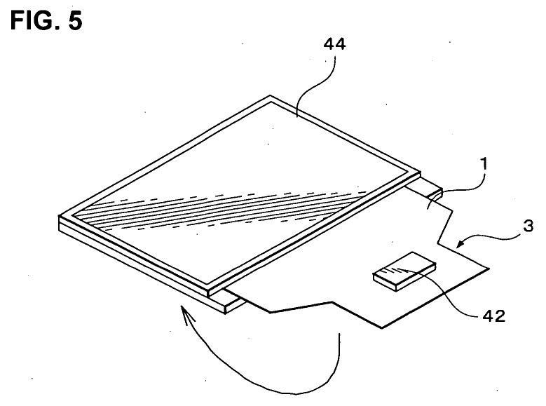

FIG. 5 is a view for describing a method for manufacturing an electronic device in accordance with an embodiment of the present invention, and more particularly, shows an example of an electronic device having a wiring substrate.

A metal layer (omitted in FIG. 5) having a predetermined pattern configuration is formed in a wiring substrate 1. A semiconductor chip 42 having an integrated circuit may be mounted (for example, face-down mounted) on the wiring substrate 1. The semiconductor chip 42 (integrated circuit) is electrically connected to the metal layer. In this manner, a semiconductor device 3 including the semiconductor chip 42 and the wiring substrate 1 may be manufactured. Then, the wiring substrate 1 (or, the semiconductor device 3) is electrically connected to a circuit board 44. Thus, the electronic device can be manufactured. It is noted that the wiring substrate 1 may be bent, as indicated by an arrow in FIG. 5.

When the circuit board 44 is an electrooptic panel, the electronic device is an electrooptic device. The electrooptic device may be a liquid crystal device, a plasma display device, an electroluminescence display device, or the like. In accordance with the present embodiment, a waste of material can be reduced, and wirings can be formed at a low cost with high accuracy, with a simple and short-time manufacturing process.

The present invention is not limited to the embodiments described above, and many modifications can be made. For example, the present invention may include compositions that are substantially the same as the compositions described in the embodiments (for example, a composition with the same function, method and result, or a composition with the same objects and result). Also, the present invention includes compositions in which portions not essential in the compositions described in the embodiments are replaced with others. Also, the present invention includes compositions that achieve the same functions and effects or achieve the same objects of those of the compositions described in the embodiments. Furthermore, the present invention includes compositions that include publicly known technology added to the compositions described in the embodiments.

1. A method for manufacturing a wiring substrate comprising the steps of
(a) providing a catalyst in first and second areas of a substrate;
(b) irradiating a vacuum ultraviolet radiation to the second area of the substrate to thereby break down an interatomic bond in the second area of the substrate;
(c) washing the substrate to thereby remove a portion of the catalyst provided in the second area; and
(d) depositing a metal layer on a portion of the catalyst remaining in the first area to thereby form a wiring composed of the metal layer along the first area.

2. A method for manufacturing a wiring substrate according to claim 1, wherein, before the step (a), a reforming layer including a C—F bond is formed in the substrate.

3. A method for manufacturing a wiring substrate according to claim 1, further comprising, before the step (b), the step of providing a surface-active agent in the first and second areas of the substrate, wherein, in the step (b), the catalyst is provided on the surface-active agent.

4. A method for manufacturing a wiring substrate according to claim 3, wherein, the surface-active agent is a cationic system surface-active agent.

5. A method for manufacturing a wiring substrate according to claim 3, wherein the surface-active agent is an anionic system surface-active agent.

6. A method for manufacturing a wiring substrate according to claim 1, wherein the substrate has at least one of a C—C, C═C, C—F, C—H, C—Cl, C—N, C—O, N—H and O—H bond.

7. A method for manufacturing a wiring substrate according to claim 1, wherein the substrate has at least a C═C bond, and the vacuum ultraviolet radiation has at least a property that can break down the C═C bond.

8. A method for manufacturing a wiring substrate according to claim 1, wherein a light source of the vacuum ultraviolet radiation is an excimer lamp having Xe gas enclosed therein.

9. A method for manufacturing a wiring substrate according to claim 1, wherein, in the step (a), the substrate is dipped in a solution including tin chloride, and then dipped in a catalyst liquid including palladium chloride, to thereby deposit palladium as the catalyst.

10. A method for manufacturing a wiring substrate according to claim 1, wherein, in the step (a), the substrate is dipped in a catalyst liquid including tin-palladium to remove tin from the substrate, to thereby deposit palladium as the catalyst.

11. A method for manufacturing an electronic device, comprising: the method for manufacturing a wiring substrate according to claim 1, and further comprising the steps of mounting a semiconductor chip having an integrated circuit on the wiring substrate, and electrically connecting the wiring substrate to a circuit substrate.
